(19) United States
(12) Patent Application Publication
(10) Pub. No.: US 2008/0099756 A1
(43) Pub. Date: May 1, 2008

(54) Semiconductor Memory with Organic Selection Transistor

(76) Inventors: Hagen Klauk, Stuttgart (DE); Marcus Halik, Erlangen (DE); Ute Zschieschang, Stuttgart (DE); Guenter Schmid, Hemhofen (DE); Christine Dehm, Nuemberg (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(21) Appl. No.: 11/597,446

(22) PCT Filed: May 30, 2005
(86) PCT No.: PCT/DE05/00927

§ 371 Date: Aug. 15, 2007

(30) Foreign Application Priority Data
May 26, 2004 (DE) 102004025675.6

(51) Int. Cl. H01L 51/00

(52) U.S. Cl. 257/40; 257/E51.001

(57) ABSTRACT

An integrated semiconductor memory with a cell array is disclosed. In one embodiment the memory includes a multiplicity of memory cells arranged in rows and columns. In at least one memory cell, an organic selection transistor is integrated in a stack arrangement above an organic storage element.

### BACKGROUND

The invention relates to an integrated semiconductor memory with a cell array having a multiplicity of memory cells which are arranged in rows and columns on a substrate and having a storage element with two electrodes and an associated selection transistor.

The market for semiconductor memories is currently served by a relatively manageable number of products:

1. Main memories having extremely short access times, such as are employed nowadays to a vast extent in computers, are almost exclusively fabricated on the basis of volatile memory architectures, particularly in DRAM technology (“dynamic random access memory”). DRAM technology is based on the storage of electronic charges in a capacitive storage element, that is to say in a capacitor. Each memory cell represents a memory unit (“bit”) and is formed by a capacitor and a selection transistor (a field effect transistor, FET). The task of the selection transistor is to electrically insulate the individual memory cells from one another and from the periphery of the cell array; as a result of switching of the respective selection transistor, any arbitrary cell can be accessed individually and in a targeted manner (“random access”). The DRAM architecture is distinguished by an extremely small space requirement (less than one square micrometer per memory cell) and extremely low fabrication costs (less than 10⁻⁸ euro per memory cell). A critical disadvantage of the DRAM concept is the volatility of the stored information, since the charge stored in the capacitor is so small (fewer than 500 000 electrons) that when the supply voltage is switched off, said charge is lost after a short time (within a few milliseconds) on account of leakage currents within the cell array.

2. Nonvolatile memories, which, even after the supply voltage has been switched off, do not lose the stored information over long periods of time (several years), are of interest for a wide range of applications (digital cameras, mobile telephones, mobile navigation instruments, computer games, etc.) and could also revolutionize the way in which computers are handled, since a computer start-up after it has been switched on would be unnecessary (“instant-on computer”). The nonvolatile memory technologies that already exist include so-called flash memories, in which the information is stored in the form of electronic charges in the gate dielectric of a silicon field effect transistor and is detected as a change in the threshold voltage of the transistor. Since the electronic charge is “trapped” in the gate dielectric of the transistor, it is not lost even when the supply voltage is switched off. An essential disadvantage of flash technology is the relatively high write and erase voltages, which arise from the need to inject the electronic charge to be stored into the gate dielectric reliably and reproducibly and to remove it from there again. Further disadvantages are the significantly longer access times in comparison with DRAM and the limited reliability on account of the high loading of the gate dielectric during writing and erasing.

3. On account of the abovementioned disadvantages of flash memories, new technologies for nonvolatile semiconductor memories based on diverse physical concepts have been developed for several years. These include ferroelectric and magnetoresistive memories, in which the stored information is read out as a change in the electrical polarization (on account of the displacement of the central atom on a perovskite crystal) and respectively as a change in an electrical resistance in an arrangement of ferromagnetic layers. For the integration of ferroelectric storage elements, it is absolutely necessary to use a selection transistor (in a manner similar to the DRAM memory cell) in order to ensure that the stored information is read out reliably. Magnetoresistive memories can be integrated without a selection transistor, in principle, since insulation of the individual storage elements is not absolutely necessary. In this case, the implementation of cells without a selection transistor has the essential advantage of a significantly smaller space requirement, which leads to a significantly higher integration density and a lower fabrication outlay per cell. However, the read-out of the stored information becomes considerably simpler and more reliable by using a selection transistor, and it is anticipated that the first magnetoresistive memory products will be based on a construction with a selection transistor.

The abovementioned memory concepts are produced and developed exclusively on silicon platforms, that is to say that the storage elements are produced exclusively on silicon substrates (“silicon wafers”) and exclusively using transistors based on silicon as the semiconductor. As an alternative thereto, both memory concepts and transistor concepts are currently being developed which manage without the use of silicon wafers and which in principle make it possible to produce mass memory devices on inexpensive glass substrates and even on flexible polymer films. Such novel mass memory devices are of interest for a multiplicity of applications, to be precise in principle both for all applications for which the ferroelectric and magnetoresistive memories are developed and for applications in which the use of silicon substrates has a disadvantageous effect on costs or on use possibilities.

The accompanying FIGS. 1a-1f illustrate six possible circuit diagrams of an optionally volatile or nonvolatile memory cell having a storage element S, which is optionally capacitive, or resistive, or based on some other physical concept, and a selection transistor T.

The six circuit diagrams illustrated in FIGS. 1a-1f differ in the arrangement and interconnection of in each case the storage element S and the selection transistor T with a word line WL, a bit line BL, a digit line DL and/or a field plate FP. It should be noted here that the basic interconnections of a storage element with a selection transistor which are shown in FIGS. 1a-1f are known per se in the prior art.

FIG. 1a illustrates that the drain terminal of the selection transistor T lies on the bit line BL and the storage element S lies between the source terminal of the selection transistor T and a field plate FP.

In accordance with FIG. 1b, the drain terminal of the selection transistor T lies on the bit line BL and the storage element lies between the source terminal of the selection transistor T and a digit line DL, which is led parallel to the word line WL.

In accordance with FIG. 1c, the drain terminal of the selection transistor T lies on the bit line BL and the storage element S lies between the source terminal of the selection transistor T and a digit line DL, which runs parallel to the bit line BL.

In accordance with FIG. 1d, the source terminal of the selection transistor T lies on a field plate FP and the storage element S lies between the drain terminal of the selection transistor T and the bit line BL.

FIG. 1e illustrates that the source terminal of the selection transistor T lies on a digit line DL and the storage element S lies between the drain terminal of the selection transistor T and the bit line BL, the digit line DL running parallel to the word line WL.

In accordance with FIG. 1f, the source terminal of the selection transistor T lies on a digit line and the storage element S lies between the drain terminal of the selection transistor T and the bit line BL, the digit line DL running parallel to the bit line BL.

The memory cell S is always selected via the word line WL, which is always connected to the gate electrode of the selection transistor T. By application of a suitable potential to the word line WL (e.g. a negative potential if the selection transistor T is a p-conducting transistor having a negative threshold voltage), the selection transistor T is opened (becomes electrically conductive) and the information stored in the storage element S can be read out in a read cycle, or can be altered in a write or erase cycle, via the bit line by application of suitable potentials to bit line BL and digit line DL or field plate FP.

An embodiment of the memory cell with a digit line DL has the advantage over an embodiment with a field plate FP that the potential on said line can be altered in a targeted manner for the cell that is currently being accessed. An embodiment of an integrated semiconductor memory with a field plate FP may lead to a smaller space requirement of the cell array.

One criterion in the realization of the memory cells is the bit line capacitance, which should be as small as possible for the sake of fast access times. Depending on whether the capacitance associated with the selection transistor T is greater or less than the capacitance associated with the storage element S, either the embodiments in accordance with FIGS. 1a-1c (in which the selection transistor T lies on the bit line BL) or the embodiments in accordance with FIGS. 1d-1f (in which the storage element S lies between bit line BL and drain terminal of the selection transistor T) have the lower bit line capacitance.

FIG. 2a illustrates a greatly simplified circuit diagram of a cell array of an integrated semiconductor memory which is embodied in accordance with FIG. 1b. That is to say that in the memory cells, the drain terminals of the selection transistors T01-T0m (of a row 0) lie on the bit lines BL0-BLm and the storage elements S01-S0m (of the row 0) in each case lie between the source terminal of the selection transistor (T01-T0m) and the digit line DL0. The digit line DL0 runs parallel to the word line WL0 (for simplification, only the selection transistors and the storage elements of a 0-th row are provided with reference symbols in FIG. 2a). FIG. 2b illustrates a greatly simplified circuit diagram of a cell array embodied in accordance with FIG. 1f. In this embodiment, the source terminals of the selection transistors T01-T0m lie on digit lines DL0-DLm and the storage elements S01-S0m in each case lie between the drain terminal of the selection transistor and the associated bit line BL0-BLm. The digit lines DL0-DLm run parallel to the bit lines BL0-BLm. Here, too, for simplification, only the selection transistors and the storage elements of the 0-th row are provided with reference symbols. It goes without saying that FIGS. 2a-2b merely reproduce an exert from a cell array comprising m columns (bit lines) and n rows (word lines). The row direction is designated by x and the column direction by y.

FIG. 3 illustrates a greatly simplified circuit diagram of a cell array which comprises m columns and n rows and which is embodied with shared bit lines. In this embodiment, the memory cells of the first, third, fifth, etc., column are staggered in each case by one row relative to the memory cells of the zeroth, second, fourth column (y direction). The circuit arrangement of the storage elements and of the selection transistors corresponds to the arrangement in accordance with FIG. 2b, the digit lines DL0, DL1 being replaced by bit lines BL1, BL3, etc.

The circuit arrangements—described above with reference to FIG. 1 and known per se from the prior art—of volatile or nonvolatile memory cells having storage elements which are optionally capacitive, or resistive, or based on some other physical concept and in each case a selection transistor and the circuit diagrams—described with reference to FIGS. 2a, 2b and 3—of differently embodied cell arrays that are likewise known in the prior art serve as a basis for an architecture of an integrated semiconductor memory according to the invention.

For these and other reasons, there is a need for the present invention.

### SUMMARY

One embodiment provides an integrated semiconductor memory which can be realized without a silicon substrate and the memory cells of which contain storage elements which are optionally capacitive, or resistive, or based on some other physical concept, in particular nonvolatile storage elements based on an organic material, and also a selection transistor realized on the basis of an organic semiconductor layer.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Life reference numerals designate corresponding similar parts.

FIGS. 1a to 1f illustrate the six circuit arrangements—already described in the introduction—of an optionally volatile or nonvolatile memory cell with an optional capacitive or resistive storage element and a selection transistor.

FIGS. 2a and 2b illustrate greatly simplified circuit diagrams of two cell arrays comprising m×n memory cells embodied respectively in accordance with FIGS. 1b and 2f.

FIG. 3 illustrates a simplified circuit diagram of a cell array embodied with shared bit lines.

FIGS. 4a-4c illustrate schematic cross sections through differently embodied memory cells according to the invention respectively in accordance with FIGS. 1a, 1b and 1c and also 1e and 1f.

FIG. 5 illustrates a schematic layout view of a cell array organized in three rows and three columns and having nine memory cells according to the invention which are constructed in accordance with the circuit of FIG. 1a and in accordance with FIG. 4a.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

The present invention provides an integrated semiconductor memory which can be realized without a silicon substrate and the memory cells of which contain storage elements which are optionally capacitive, or resistive, or based on some other physical concept, in particular nonvolatile storage elements based on an organic material, and also a selection transistor realized on the basis of an organic semiconductor layer.

In one embodiment, the present invention provides an integrated semiconductor memory with a cell array comprising a multiplicity of memory cells which are arranged in rows and columns on a substrate and in each case have a storage element with two electrodes and an associated selection transistor. The control electrodes of the selection transistors of the individual rows are connected by word lines running in the row direction and one controlled electrode of the selection transistors of the individual columns being connected either to a bit line running in the column direction or to a digit line or to a field plate, and one electrode of each storage element being connected to the other controlled electrode of the associated selection transistor and the other electrode of each storage element being connected either to a bit line, a digit line or a field plate. The integrated semiconductor memory is distinguished according to the invention by the fact that each memory cell has an organic storage element with an organic active layer arranged between the two electrodes and a selection transistor comprising a field effect transistor with an organic semiconductor layer, and each selection transistor and the assigned storage element are stacked one above another on the substrate.

In the case of an integrated semiconductor memory according to the invention, the substrate need not be a silicon substrate, but rather may include glass, a polymer film, a metal film coated with an insulating layer, or else paper and other substrates that do not contain silicon.

All memory cells embodied according to the invention use a stacked construction, that is to say that the storage element and the selection transistor are realized in a manner lying one above another on the substrate. In comparison with a planar construction, in which the storage element and selection transistor lie alongside one another, the stacked construction has the advantage of a significantly smaller space requirement.

In one exemplary embodiment, the selection transistors are integrated in an inverted coplanar arrangement, in which the organic semiconductor layer is arranged above the gate electrode and the source and drain electrodes of the selection transistors are in direct contact with the gate dielectric.

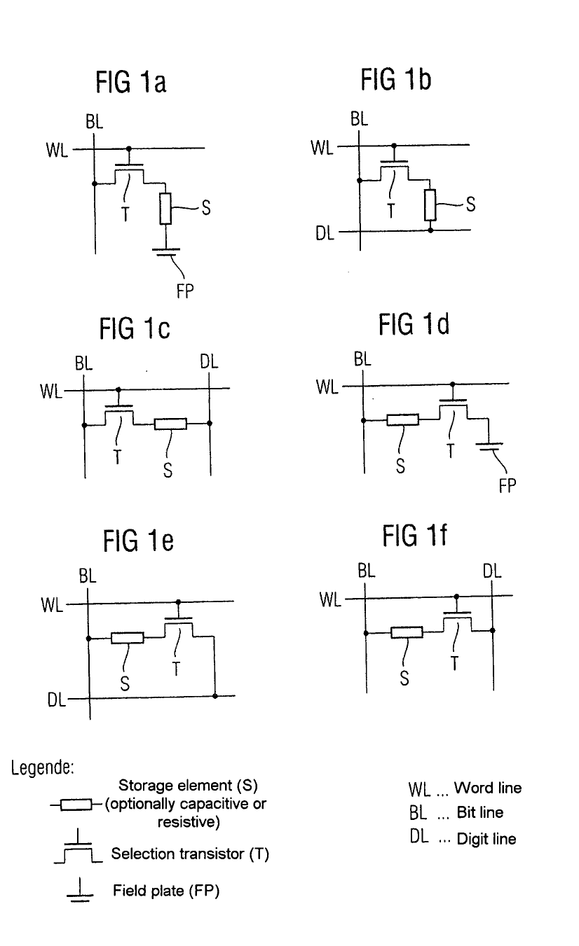

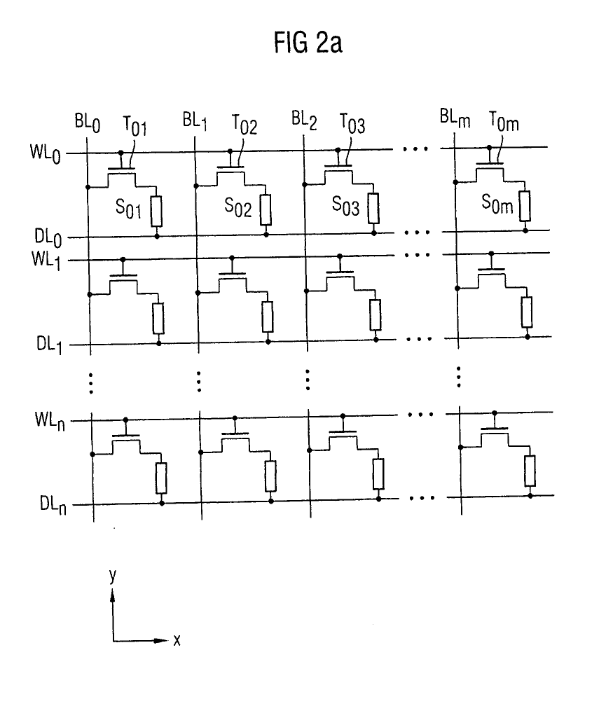

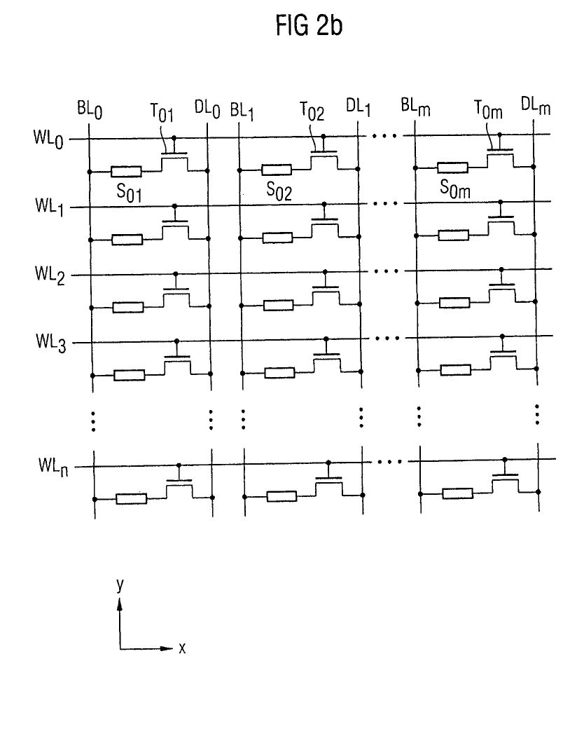

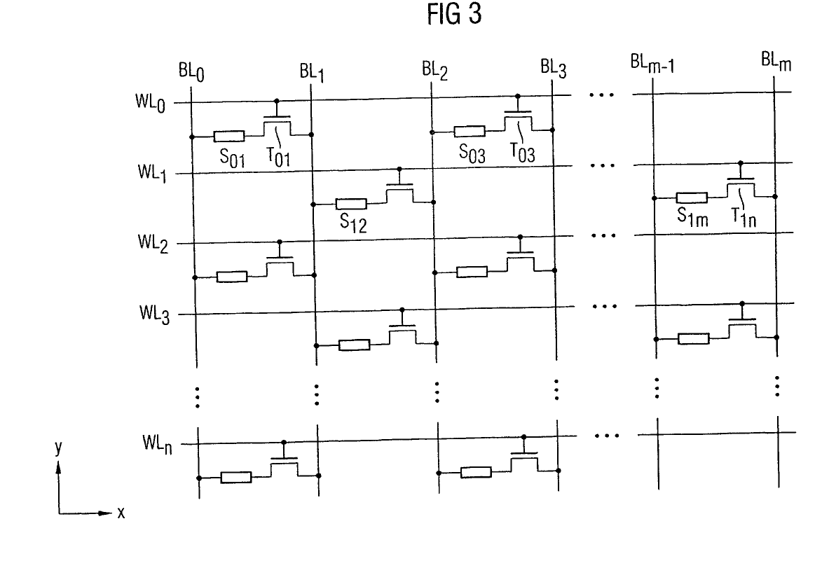

In principle, all of the circuit variants of integrated semiconductor memories described previously with reference to FIGS. 1a-1f, 2a, 2b and 3 can be realized with an integrated semiconductor memory according to the invention.

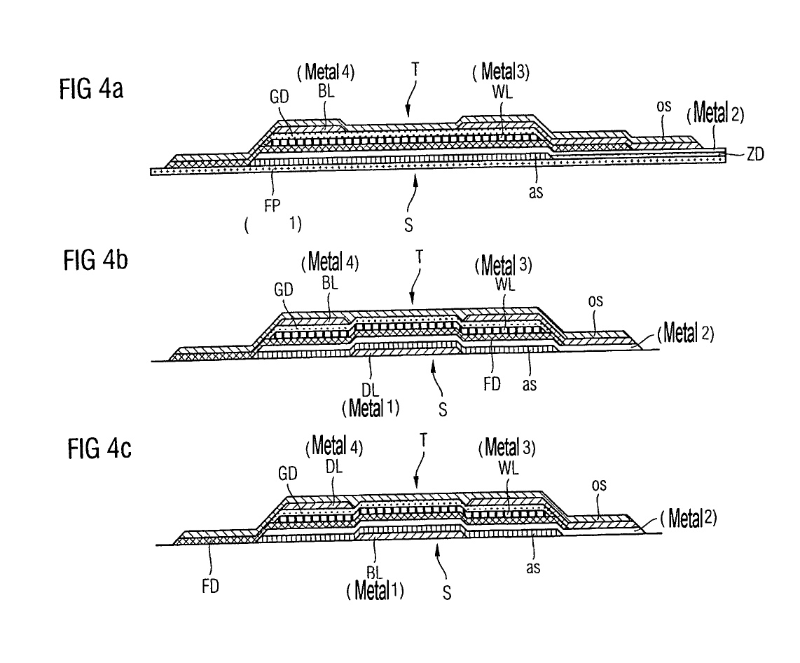

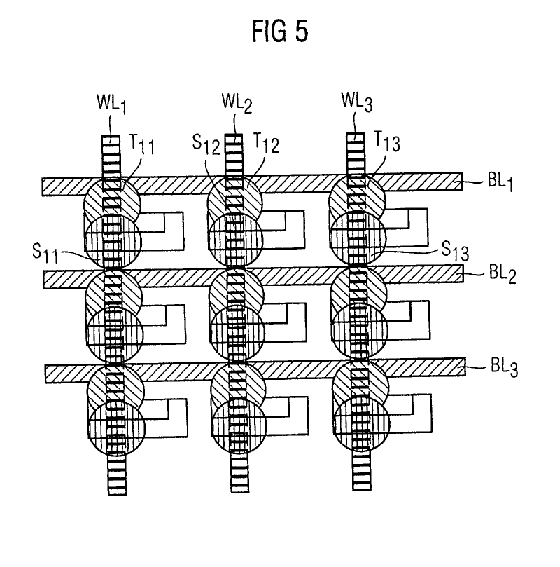

FIGS. 4a-4c illustrate schematic cross sections of memory cells of a semiconductor memory according to the invention. Therein, each selection transistor T with the associated organic storage element S are integrated in a manner stacked one above another on a substrate (not shown), to be precise in such a way that the selection transistor T lies above the assigned storage element S in the vertical direction. All of the exemplary embodiments of memory cells of an integrated semiconductor memory according to the invention as illustrated in FIGS. 4a-4c contain a selection transistor T which is integrated in an inverted coplanar arrangement. In the inverted coplanar design, the organic semiconductor layer os of the selection transistor T is arranged such that it lies on top (above the gate electrode), that is to say in an inverted manner with respect to the customary silicon field effect transistor, in which the gate electrode lies on top, and the source and drain contacts are in direct contact with the gate dielectric GD (in contrast to the staggered embodiment, in which the organic semiconductor layer os is situated between the gate dielectric and the source and drain contacts. The inverted coplanar embodiment is the design most frequently used for organic transistors; in principle, however, all of the memory cells illustrated in FIGS. 1a-1f can also be realized with organic selection transistors in any other design desired.

FIG. 4a illustrates the schematic cross section of a first preferred exemplary embodiment of a memory cell according to the invention in a stacked design which realizes a circuit in accordance with FIG. 1a. The bottommost metal layer (metal 1) lying on the substrate (not illustrated) is embodied as a field plate FP and, in accordance with the circuit variant of FIG. 1a, simultaneously forms the bottom electrode of the storage element S. The active layer as of the storage element S lies above the bottommost metal layer (metal 1) forming the field plate FP. A top electrode of the storage element S is situated in the second metal layer (metal 2) and is insulated from the field plate FP (metal 1) by an intermediate dielectric ZD. Lying above the top electrode of the storage element S is a field dielectric FD for insulation between metal 2 and an overlying word line WL (metal 3). In accordance with the circuit shown in FIG. 1a, the word line WL is identical with the gate electrode of the selection transistor T. A gate dielectric GD is formed above the word line WL or the gate electrode of the selection transistor T. The drain contact of the selection transistor T, said drain contact lying above the gate dielectric GD, simultaneously forms the bit line BL (metal 4), while the source contact at the right-hand edge of FIG. 4a is in contact with the top electrode (metal 2) of the storage element S. As mentioned, the organic semiconductor layer os of the selection transistor T integrated in an inverted coplanar embodiment forms the topmost layer in FIG. 1.

The cross-sectional view in accordance with FIG. 4b illustrates a second preferred exemplary embodiment of a memory cell according to the invention, in which the organic selection transistor T is likewise integrated in a manner stacked above the organic storage element S. This memory cell realizes the memory circuit shown in FIG. 1b and FIG. 1c with a digit line DL that is optionally routed parallel to the word line WL or parallel to the bit line BL. The digit line DL forms the bottommost metal layer (metal 1) lying on the substrate (not shown) and simultaneously forms the bottom electrode of the storage element S. As is already the case in the exemplary embodiment in accordance with FIG. 4a, the top electrode (metal 2) of the storage element S is connected to the source contact of the selection transistor T, while the bit line BL (metal 4) simultaneously forms the drain contact of the selection transistor T. In the exemplary embodiment illustrated in FIG. 4b as well, the selection transistor T is embodied in an inverse coplanar design, so that the organic semiconductor layer os is the topmost layer.

FIG. 4c illustrates a schematic cross section of a third preferred exemplary embodiment of an organic memory cell having an organic selection transistor T integrated in a manner stacked above an organic storage element S. The arrangement of FIG. 4c realizes the circuit in accordance with FIGS. 1e and 1f, to be precise with a digit line DL which is optionally routed parallel to the word line WL or parallel to the bit line BL. A comparison with FIG. 4b shows that in the memory cell according to the invention which is shown in FIG. 4c and corresponds to the third exemplary embodiment, the bit line BL lies in the bottommost metal layer (metal 1) and the digit line DL lies in the topmost metal layer (metal 4), that is to say that digit line DL and bit line BL are simply interchanged in their position in comparison with the second exemplary embodiment in accordance with FIG. 4b.

In the third exemplary embodiment shown in FIG. 4c as well, the selection transistor T is embodied in an inverted coplanar design, so that the organic semiconductor layer os forms the topmost layer.

The realization of the exemplary embodiments shown in FIGS. 4a-c requires the deposition and patterning of the following functional layers on the substrate (not shown), the order of these functional layers, from the substrate (not shown), proceeding from bottom to top, that is to say in the vertical direction:
1. Metal 1 (field plate FP (FIG. 4a) or digit line DL (FIG. 4b) or bit line BL (FIG. 4c) and bottom electrode of the storage element S);
2. Active layer as of the storage element S;
3. Intermediate dielectric ZD (only FIG. 4a);
4. Metal 2 (top electrode of the storage element S);
5. Field dielectric FD (insulation between metal 2 and overlying metal layers);
6. Metal 3 (word line WL and gate electrode of the selection transistor T);
7. Gate dielectric GD (insulation between gate electrode and organic semiconductor layer os of the selection transistor T);
8. Metal 4 (bit line BL and source and drain contacts of the selection transistor T (FIGS. 4a and 4b) and digit line DL or source contact of the selection transistor T (FIG. 4c));
9. Organic semiconductor layer os of the selection transistor T.

What are suitable as substrate are, by way of example, glass, polymer film, metal film (coated with an insulating layer, paper and other materials). In particular, the use of silicon as substrate is indeed possible but not necessary. The layers: “Metal-1”, “Metal-2”, “Metal-3” and “Metal-4” must be metallically conductive, that is to say be produced by deposition of inorganic metals (for example aluminum, copper, titanium, gold), conductive oxides (for example indium tin oxide) or conductive polymers (for example polyaniline). The gate dielectric GD, the intermediate dielectric ZD and the field dielectric FD must have good insulator properties; both inorganic insulators such as, for example, silicon oxide and aluminum oxide and in particular also insulating polymers such as, for example polyvinyl phenol are suitable for this. A series of materials, in particular pentazene, diverse oligothiophenes and polythiophene, are appropriate as organic semiconductor layer os for the selection transistor. A series of approaches both for capacitive and for resistive storage effects are currently being discussed for the embodiment of the active layer as of the storage element.

FIG. 5 illustrates a schematic layout view of a cell array comprising memory cells according to the invention (storage elements S11, S12, S13 and selection transistors T11, T12, T13 stacked above them) in accordance with the circuit shown in FIG. 1a and the exemplary embodiment illustrated in FIG. 4a. The cell array is organized, in a simplifying fashion, in three rows and three columns which are respectively defined by three bit lines BL1, BL2, BL3 and three word lines WL1, WL2 and WL3. For the sake of better clarity, a field plate, field dielectric, intermediate dielectric and gate dielectric are not shown in FIG. 5.

An exemplary embodiment of a method for producing a semiconductor memory according to the invention, that is to say its cell array, is described below.

In accordance with the exemplary embodiment illustrated in FIGS. 4a and 5, a chromium mask is produced for each functional layer to be patterned, which mask permits the patterning of the deposited layers by means of photolithographic processes. A layer of aluminum having a thickness of approximately 30 nm is applied to a glass substrate, for example, by means of thermal vaporization, said layer being patterned by means of photolithography and wet-chemical etching in aqueous potassium hydroxide solution in order to define the first metal layer (metal 1; field plate, bottom electrode of the storage element). In a second step, the active layer as of the storage element S (for example a polymer characterized by an electrical resistance that can be altered in a targeted manner) is deposited and patterned. The intermediate dielectric ZD is subsequently deposited and patterned. A layer of titanium having a thickness of approximately 30 nm is subsequently applied by means of thermal vaporization, which layer is patterned by means of photolithography and wet-chemical etching in aqueous hydrogen fluoride solution in order to define the second metal layer (metal 2; top electrode of the storage element). In order to produce the field dielectric FD, a layer of polyvinyl phenol having a thickness of approximately 300 nm is spun on from a suitable organic solvent (for example propylene glycol monomethyl ether acetate PGMEA), thermally crosslinked (at approximately 200° C.) and patterned by means of photolithography and etching in an oxygen plasma. In the next step, a layer of aluminum having a thickness of approximately 30 nm is applied by means of thermal vaporization, which layer is patterned by means of photolithography and wet-chemical etching in aqueous potassium hydroxide solution in order to define the third metal layer (metal 3; gate electrode of the selection transistor, word line WL). The gate dielectric GD is subsequently defined, for example by spinning on and photolithographically patterning a layer of polyvinyl phenol having a thickness of approximately 100 nm or by applying an electrically insulating molecular self-assembling monolayer (SAM) having a thickness of approximately 3 nm. In the next step, a layer of gold having a thickness of approximately 30 nm is applied by vapor deposition and the fourth metal layer (metal 4; source and drain contacts of the selection transistor T, bit line BL) is defined by means of photolithography and wet-chemical etching. A layer of pentazene having a thickness of 30 nm is subsequently applied by vapor deposition as organic semiconductor layer os of the selection transistor and is patterned by means of photolithography (with the aid of a water-soluble photoresist) and plasma etching.

To summarize, the invention specifies a semiconductor memory in which an organic selection transistor, that is to say a field effect transistor having an organic semiconductor layer, is integrated above an organic storage element, that is to say an organically active layer arranged between two electrodes and having optionally capacitive or resistive electrical storage behavior, with the formation of a stacked memory cell on an arbitrary substrate, which need not comprise silicon. The storage element may optionally be a storage element which is capacitive, or resistive, or based on some other physical concept, in particular a nonvolatile storage element. In comparison with an arrangement in which the selection transistor and storage element are integrated alongside one another, this stacked arrangement according to the invention affords the advantage of a considerable space saving. In the course of the integration, it is advantageously the case that the gate electrode of the selection transistor may be embodied as a word line and the drain or source contact of the selection transistor or the electrodes of the storage element may be embodied either as a bit line, as a digit line or as a field plate.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1-12. (canceled)

13. A semiconductor memory comprising:
a first electrode and a second electrode;
an organic storage element; and
an organic selection transistor.

14. The memory of claim 13, comprising:
wherein the organic storage element includes an organic active layer between the first electrode and the second electrode.

15. The memory of claim 13, comprising:
wherein the organic storage element and the organic selection transistor are positioned in a stacked arrangement on a substrate.

16. The memory of claim 15, comprising wherein the substrate is non-silicon.

17. The memory of claim 13, comprising wherein the organic selection transistor is located above the organic storage element in a vertical direction.

18. The memory of claim 15, comprising wherein the substrate comprises glass.

19. The memory of claim 15, comprising wherein the substrate has a polymer film.

20. The memory of claim 15, comprising wherein the substrate is a metal film coated with an insulating layer.

21. The memory of claim 13, wherein the substrate comprises paper.

22. The memory of claim 13, comprising:
wherein the organic selection transistor comprises a field effect transistor with an organic semiconductor layer.

23. The memory of claim 13, comprising:
wherein the organic storage element is configured as a capacitive storage element.

24. The memory of claim 13, comprising:
Wherein the organic storage element is configured as a resistive storage element.

25. The memory of claim 13, comprising wherein the organic selection transistor is integrated in an inverted coplanar arrangement in which an organic semiconductor layer of the organic selection transistor is arranged above its gate electrode and its source and drain contact is in direct contact with the gate dielectric.

26. The memory of claim 13, comprising wherein a drain contact of the organic selection transistor lies on a bit line and the organic storage element lies between a source contact of the organic selection transistor and a field plate.

27. The memory of claim 13, wherein a drain contact of the organic selection transistor lies on a bit line and the organic storage element lies between a source contact of the organic selection transistor and a digit line.

28. The memory of claim 13, wherein a source contact of the organic selection transistor lies on a digit line and the organic storage element lies between a drain contact of the organic selection transistor and a bit line, the digit line running parallel to a word line.

29. The memory as of claim 13, wherein a source contact of the organic selection transistor lies on a digit line and the organic storage element lies between a drain contact of the organic selection transistor and the bit line, the digit line running parallel to a bit line.

30. A semiconductor memory comprising:
a first electrode and a second electrode;
an organic storage element; and
an organic selection transistor.

31. A semiconductor memory with a cell array comprising:
a multiplicity of memory cells which are arranged in rows and columns on a substrate and in each case have a storage element with two electrodes and an associated selection transistor, the control electrodes of the selection transistors of the individual rows being connected by word lines running in the row direction and one controlled electrode of the selection transistors of the individual columns being connected either to a bit line running in the column direction or to a digit line or to a field plate, and one electrode of each storage element being connected to the other controlled electrode of the associated selection transistor and the other electrode of each storage element being connected either to a bit line, a digit line or a field plate; and
wherein each memory cell has an organic storage element with an organic active layer arranged between the two electrodes and a selection transistor comprising a field effect transistor with an organic semiconductor layer, and each selection transistor and the assigned storage element are stacked one above another on the substrate.

32. The semiconductor memory as claimed in claim 31, comprising wherein the substrate is not a silicon substrate.

33. The semiconductor memory as claimed in claim 31, comprising wherein each selection transistor is located above the assigned storage element in a vertical direction.

34. The semiconductor memory as claimed in claim 31, comprising wherein the substrate comprises glass.

35. The semiconductor memory as claimed in claim 31, comprising wherein the substrate has a polymer film.

36. The semiconductor memory as claimed in claim 31, comprising wherein the substrate is a metal film coated with an insulating layer.

37. The semiconductor memory as claimed in claim 31, comprising wherein the substrate comprises paper.

38. The semiconductor memory as claimed in claim 31, comprising wherein the selection transistors are integrated in an inverted coplanar arrangement in which the organic semiconductor layer of each selection transistor is arranged above its gate electrode and its source and drain contact is in direct contact with the gate dielectric.

39. The semiconductor memory as claimed in claim 31, comprising wherein the drain contact of the selection transistor lies on the bit line and the storage element lies between the source contact of the selection transistor and a field plate.

40. The semiconductor memory as claimed in 31, wherein the drain contact of the selection transistor lies on the bit line and the storage element lies between the source contact of the selection transistor and the digit line.

41. The semiconductor memory as claimed in 31, wherein the source contact of the selection transistor lies on the digit line and the storage element lies between the drain contact of the selection transistor and the bit line, the digit line running parallel to the word line.

42. The semiconductor memory as claimed in 31, wherein the source contact of the selection transistor lies on the digit line and the storage element lies between the drain contact of the selection transistor and the bit line, the digit line running parallel to the bit line.
